(19) United States
(12) Patent Application Publication
(10) Pub. No.: US 2017/0008015 A1
(43) Pub. Date: Jan. 12, 2017

(54) SUBSTRATE PROCESSING APPARATUS

(71) Applicant: WONIK IPS CO., LTD., Gyeonggi-do (KR)

(72) Inventors: Doo Hyun LA, Gyeonggi-do (KR); Dong Ho RYU, Gyeonggi-do (KR); Ju Sung PARK, Gyeonggi-do (KR); Ju Sung PARK, Gyeonggi-do (KR); Sang Woo LEE, Gyeonggi-do (KR)

(21) Appl. No.: 15/196,293

(22) Filed: Jun. 29, 2016

(30) Foreign Application Priority Data
Jul. 7, 2015 (KR) 10-2015-0096725

(51) Int. Cl. B05B 1/18; B05B 1/00; C23C 16/455

(52) U.S. Cl. CPC B05B 1/185; C23C 16/45544; B05B 1/005

(57) ABSTRACT

Provided is a substrate processing apparatus capable of improving thickness uniformity. The substrate processing apparatus includes a process chamber including a shower head, a feeding block including a tube to provide a source gas and a reaction gas to the shower head, and a mixing block configured to provide a channel connected between the shower head and the feeding block to mix the source gas and the reaction gas, and the mixing block includes an internal space having a cross-sectional area larger than the cross-sectional area of the tube provided in the feeding block, and a collision part provided on a path of a gas mixture of the source gas and the reaction gas to collide with the gas mixture.

### CROSS-REFERENCE TO RELATED PATENT APPLICATION

This application claims the benefit of Korean Patent Application No. 10-2015-0096725, filed on Jul. 7, 2015, in the Korean Intellectual Property Office, the disclosure of which is incorporated herein in its entirety by reference.

### BACKGROUND

1. Field

The present invention relates to a substrate processing apparatus and, more particularly, to a substrate processing apparatus capable of thickness uniformity of a thin film deposited using a source gas and a reaction gas.

2. Description of the Related Art

As semiconductor devices are highly integrated, patterns having fine line widths are required. As such, double patterning technology (DPT) has been proposed to implement patterns having fine line widths using commercialized exposure equipment, and atomic layer deposition (ALD) technology has been proposed to deposit a thin film having an excellent step coverage on a stepped pattern having a large aspect ratio. Meanwhile, since large-diameter wafers are required to increase productivity of semiconductor devices, process uniformity over a whole surface of the wafer is regarded as a significant issue. Currently, when a DPT or ALD process is performed on a large-diameter wafer, uniformity of a thin film deposition process is a major problem to be solved.

### SUMMARY

The present invention provides a substrate processing apparatus capable of thickness uniformity of a deposited thin film. However, the scope of the present invention is not limited thereto.

According to an aspect of the present invention, there is provided a substrate processing apparatus including a process chamber including a shower head, a feeding block including a tube to provide a source gas and a reaction gas to the shower head, and a mixing block configured to provide a channel connected between the shower head and the feeding block to mix the source gas and the reaction gas, wherein the mixing block includes an internal space having a cross-sectional area larger than the cross-sectional area of the tube provided in the feeding block, and a collision part provided on a path of a gas mixture of the source gas and the reaction gas to collide with the gas mixture.

The tube provided in the feeding block may include a first tube capable of providing the source gas, a second tube capable of providing the reaction gas, and a third tube directly connected to the first and second tubes, extending to be connected to the internal space of the mixing block, and capable of providing the source gas and the reaction gas, and the internal space of the mixing block may be in fluid communication with the third tube and have a cross-sectional area larger than the cross-sectional area of the third tube to diffuse the gas mixture of the source gas and the reaction gas.

The collision part may include a collision surface which is not parallel but diagonal or perpendicular to a direction from the feeding block toward the shower head.

The internal space provided in the mixing block may include multi-stage cylindrical spaces having decreasing cross-sectional areas.

The internal space provided in the mixing block may include a truncated conical space having a continuously decreasing cross-sectional area.

The internal space provided in the mixing block may include a cylindrical space having a uniform cross-sectional area.

Each of the first and second tubes may lie perpendicular to the third tube and the first and second tubes may extend in opposite directions from the third tube.

The first and second tubes may be located at different levels.

The first and second tubes may located at the same level.

The mixing block may include an insulating member between the feeding block and the shower head.

The mixing block may be made of a ceramic material or Al₂O₃.

The source gas may include a silicon-containing gas, the reaction gas may include an oxygen-containing gas, and the gas mixture may further include an inert gas.

### BRIEF DESCRIPTION OF THE DRAWINGS

The above and other features and advantages of the present invention will become more apparent by describing in detail embodiments thereof with reference to the attached drawings in which:

FIG. 1A is a conceptual view of a substrate processing apparatus according to an embodiment of the present invention;

FIG. 1B is a conceptual view of a substrate processing apparatus according to a comparative example of the present invention;

FIG. 1C is a view showing the configuration of a tube provided in a feeding block of the substrate processing apparatus according to an embodiment of the present invention;

FIG. 1D is a view showing a unit cycle of a thin film deposition method using the substrate processing apparatus according to an embodiment of the present invention;

FIG. 2 is a view showing thickness uniformities of thin films deposited on substrates using substrate processing apparatuses according to an embodiment and a comparative example of the present invention.

FIGS. 3A, 3B, 3C, 3D, 3E and 3F are views of various types of mixing blocks for configuring substrate processing apparatuses according to embodiments of the present invention; and

FIG. 4 is a view showing thickness uniformities of thin films deposited on substrates using substrate processing apparatuses including the mixing blocks illustrated in FIGS. 3A to 3E.

### DETAILED DESCRIPTION

Hereinafter, the present invention will be described in detail by explaining embodiments of the invention with reference to the attached drawings.

It will be understood that when an element such as a layer, a pattern, a region, or a substrate is referred to as being “on” another element, it can be directly on the other element, or intervening elements may also be present. In contrast, when an element is referred to as being “directly on” another element, there are no intervening elements present.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing. In the drawings, the thicknesses or sizes of layers are exaggerated for clarity. Like reference numerals in the drawings denote like elements.

A thin film deposition method according to embodiments of the present invention may be implemented using chemical vapor deposition (CVD) or atomic layer deposition (ALD).

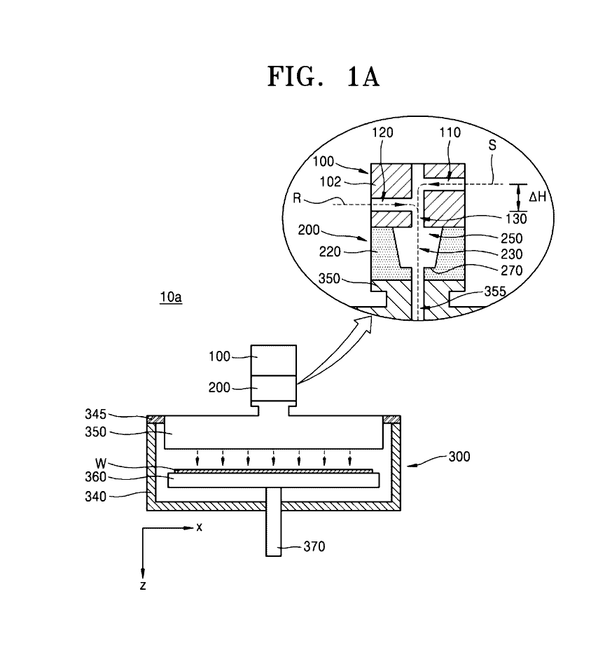

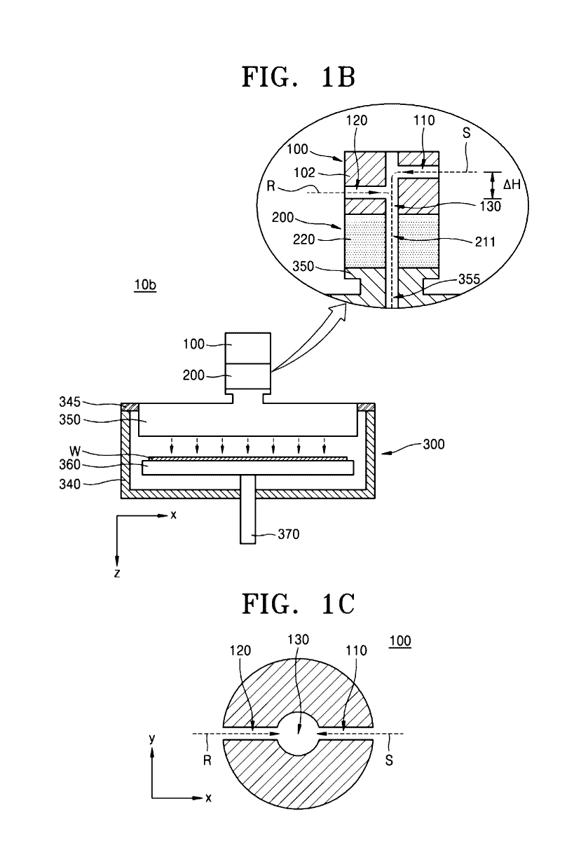

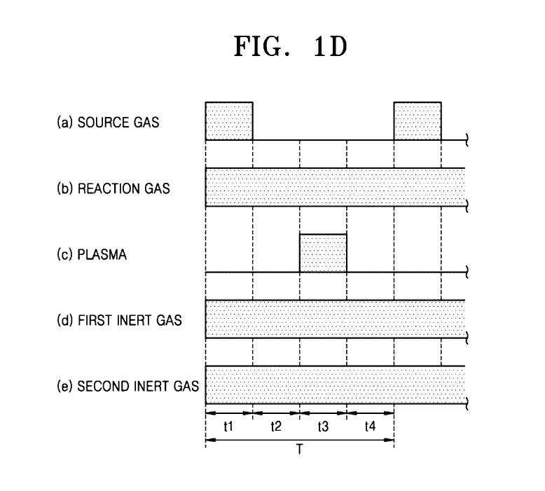

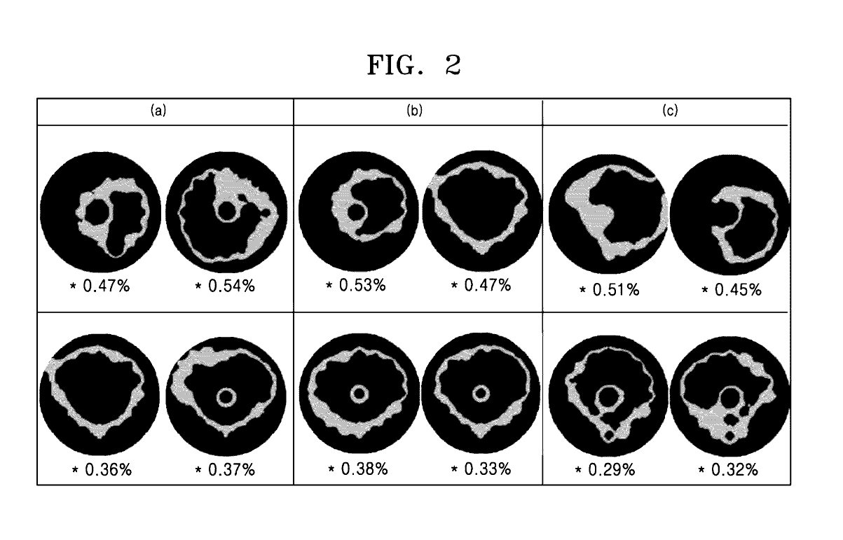

FIG. 1A is a conceptual view of a substrate processing apparatus 10a according to an embodiment of the present invention.

Referring to FIG. 1A, the substrate processing apparatus 10a according to an embodiment of the present invention includes a process chamber 300 including a shower head 350, a feeding block 100 including a tube to provide a source gas S and a reaction gas R to the shower head 350, and a mixing block 200 configured to provide a channel connected between the shower head 350 and the feeding block 100 to mix the source gas S and the reaction gas R.

The mixing block 200 includes an internal space 250 having a cross-sectional area larger than the cross-sectional area of the tube provided in the feeding block 100, and a collision part 270 provided on a path of the gas mixture of the source gas S and the reaction gas R to collide with the gas mixture.

The tube provided in the feeding block 100 includes a first tube 110 capable of providing the source gas S, a second tube 120 capable of providing the reaction gas R, and a third tube 130 directly connected to the first and second tubes 110 and 120, extending to be connected to a mixing channel 230 of the mixing block 200, and capable of providing the source gas S and the reaction gas R. The first tube 110 may provide not only the source gas S but also an inert gas serving as a carrier gas for carrying the source gas S, the second tube 120 may provide not only the reaction gas R but also an inert gas serving as a carrier gas for carrying the reaction gas R, and the third tube 130 may provide not only the source gas S and the reaction gas R but also the inert gases.

The source gas S may be appropriately selected depending on the type of a thin film to be deposited on a substrate W. For example, if the thin film to be deposited is a silicon oxide layer, the source gas S may include a silicon-containing gas such as SiH₄, SiCl₄, Si₂Cl₆, Si(NO₂)₄, Si(N₂O₂)₂, SiF₄, SiF₆, or Si(CNO)₄, and the reaction gas R may include an oxygen-containing gas such as 02. Alternatively, depending on the type of a thin film to be deposited, the source gas S may include a mixture of silicon (Si) and hydrogen (H), a mixture of Si and nitrogen (N), a mixture of Si and fluorine (F), a mixture of Si and oxygen (O), or a mixture of Si, N, and O. The above-mentioned types of thin film, source gas, and reaction gas are only examples and the technical idea of the present invention is not limited thereto.

The process chamber 300 includes the shower head 350, and a chamber lead 345 supporting the shower head 350. The shower head 350 includes an inlet channel 355 provided in a body thereof. The gas mixture of the source gas S and the reaction gas R provided through the inlet channel 355 passes through a diffusion plate and reaches the substrate W mounted on a susceptor 360. Plasma may be implemented in a space defined by chamber walls 340 by applying high-frequency power to the process chamber 300. Specifically, plasma may be implemented between the shower head 350 and the substrate W mounted on the susceptor 360.

The mixing block 200 is provided between the feeding block 100 and the shower head 350. The mixing block 200 includes a body 220, and the mixing channel 230 provided in the body 220. The mixing channel 230 may be a channel connected between the feeding block 100 and the shower head 350. For example, the mixing channel 230 may be connected to the third tube 130 of the feeding block 100 and the inlet channel 355 of the shower head 350.

The mixing channel 230 includes the internal space 250 capable of expanding a cross-sectional area of the path of the gas mixture passed through the feeding block 100 to diffuse the gas mixture of the source gas S and the reaction gas R. For example, the internal space 250 may be connected to the third tube 130 and have a cross-sectional area larger than the cross-sectional area of the third tube 130 to diffuse the gas mixture of the source gas S and the reaction gas R.

Furthermore, the mixing block 200 includes the collision part 270 provided on a path of the gas mixture of the source gas S and the reaction gas R to collide with the gas mixture. The collision part 270 may include a collision surface which is not parallel but diagonal or perpendicular to a direction proceeding from the feeding block 100 toward the shower head 350. Since a vortex is generated when the gas mixture diffused in the internal space 250 proceeds and collides with the collision part 270, uniformity of the gas mixture may be improved.

At least a part of the internal space 250 may be located prior to the collision part 270 on the path of the gas mixture. The path of the gas mixture includes a path proceeding from the feeding block 100 toward the shower head 350 and thus may include, for example, a path of the gas mixture proceeding downward in FIG. 1A. Meanwhile, the vortex includes a swirling flow in a direction opposite to a main flow (e.g., the downward flow of the gas mixture) due to rotation of a fluid. For example, a strong rotative flow of a fluid may be understood as a part of the vortex.

To provide the uniformly mixed gas mixture of the source gas S and the reaction gas R into the process chamber 300 is a significant process factor for thickness uniformity of a thin film deposited on the substrate W. Actually, the present inventor has found that the uniformly mixed gas mixture is not implemented by merely providing the source gas S and the reaction gas R into the same space. The present inventor has found that uniformity of the gas mixture of the source gas S and the reaction gas R is improved by diffusing the gas mixture using the internal space 250 of the mixing block 200 to reduce the density thereof and then generating a vortex using the collision part 270 located on the path of the gas mixture, and thus thickness uniformity of a thin film deposited on the substrate W is greatly improved.

According to an embodiment of the present invention, the above-described mixing block 200 may include an insulating member provided between the feeding block 100 and the shower head 350. Since a ceramic block for plasma insulation may be intervened between the feeding block 100 and the shower head 350, the mixing block 200 may simultaneously perform a function for uniform mixing of the gas mixture and a function for plasma insulation.

However, according to a modified embodiment of the present invention, the mixing block 200 may configure a part of the feeding block 100. In this case, the body 220 of the mixing block 200 may be a part of a body of the feeding block 100, and the mixing channel 230 of the mixing block 200 may be provided in the feeding block 100.

According to another modified embodiment of the present invention, the mixing block 200 may configure a part of the shower head 350. In this case, the body 220 of the mixing block 200 may be a part of a body of the shower head 350, and the mixing channel 230 of the mixing block 200 may be provided in the shower head 350.

FIG. 1B is a conceptual view of a substrate processing apparatus 10b according to a comparative example of the present invention.

Referring to FIG. 1B, the mixing block 200 for configuring the substrate processing apparatus 10b according to a comparative example of the present invention may include a linear channel 211 penetrating through the body 220. Since the linear channel 211 is connected to and has the same cross-sectional area as the third tube 130 of the feeding block 100 and is connected to and has the same cross-sectional area as the inlet channel 355 of the shower head 350, the gas mixture of the source gas S and the reaction gas R is hardly diffused due to pressure drop or hardly generates a vortex using a collision surface. In the substrate processing apparatus 10b having the above-described configuration, thickness uniformity of a thin film deposited on the substrate W is relatively bad.

FIG. 1C is a view showing the configuration of the tube provided in the feeding block 100 of the substrate processing apparatus 10a according to an embodiment of the present invention.

Referring to FIGS. 1A and 1C, the first tube 110 perpendicularly crosses the third tube 130, and the second tube 120 also perpendicularly crosses the third tube 130. The first and second tubes 110 and 120 may have a level difference ΔH therebetween in a height direction of the third tube 130. For example, as illustrated in FIG. 1A, the level of the first tube 110 capable of providing the source gas S may be higher than the level of the second tube 120 capable of providing the reaction gas R. According to a modified embodiment, the level of the first tube 110 capable of providing the source gas S may be lower than the level of the second tube 120 capable of providing the reaction gas R. According to another modified embodiment, the level of the first tube 110 capable of providing the source gas S may be equal to the level of the second tube 120 capable of providing the reaction gas R. In this case, the first and second tubes 110 and 120 may be located on the same plane.

Referring to FIG. 1C, the first and second tubes 110 and 120 may be located to form an angle of 180° about the third tube 130. That is, the first and second tubes 110 and 120 extend in opposite directions from the third tube 130. In this case, viewing from above the substrate processing apparatus 10a, the first and second tubes 110 and 120 may be symmetrically located with respect to the third tube 130. If the first and second tubes 110 and 120 have the same level, the source gas S passed through the first tube 110 and the reaction gas R passed through the second tube 120 may be provided toward the third tube 130 from opposite directions. According to a modified embodiment of the present invention, the first and second tubes 110 and 120 may be located to form an angle of 90° about the third tube 130.

According to the structure of the feeding block 100 described above referring to FIGS. 1A and 1C, uniformity of the gas mixture of the source gas S and the reaction gas R may be efficiently improved. That is, the source gas S and the reaction gas R are mixed before being supplied to the process chamber 300 and, more particularly, the source gas S passed through the first tube 110 and the reaction gas R passed through the second tube 120 are mixed in the third tube 130 due to flow interference therebetween. As such, conductance and flow properties of the source gas S and the reaction gas R may be controlled and thus thickness uniformity of a thin film deposited on the substrate W may be improved.

However, according to the technical idea of the present invention, the above-described mixing block 200 is a critical element and the above-described feeding block 100 is optionally adoptable.

A description is now given of a thin film deposition method using the above-described substrate processing apparatus 10a.

Referring to FIGS. 1A and 1D, in the thin film deposition method, a unit cycle T including providing the source gas S onto the substrate W located in the process chamber 300 in such a manner that at least a part of the source gas S is adsorbed onto the substrate W; and providing the reaction gas R onto the substrate W to deposit a unit film on the substrate W may be performed at least one time.

For example, the unit cycle T which is performed at least one time to deposit the unit film on the substrate W may include providing the source gas S onto the substrate W located in the process chamber 300 in such a manner that at least a part of the source gas S is adsorbed onto the substrate W (S1), providing the reaction gas R onto the substrate W (S2), activating the reaction gas R on the substrate W to a plasma state (S3), providing a first inert gas onto the substrate W (S4), and providing a second inert gas onto the substrate W (S5). At least a part of operations S1 to S5 may be simultaneously performed.

For example, if the unit cycle T sequentially includes a first period t1, a second period t2, a third period t3, and a fourth period t4, operation S1 for providing the source gas S onto the substrate W may be performed during the first period t1, operation S2 for providing the reaction gas R onto the substrate W may be continuously performed during the first to fourth periods t1 to t4, operation S3 for activating the reaction gas R on the substrate W to the plasma state may be performed during the third period t3, operation S4 for providing the first inert gas onto the substrate W may be continuously performed during the first to fourth periods t1 to t4, and operation S5 for providing the second inert gas onto the substrate W may be continuously performed during the first to fourth periods t1 to t4.

A detailed description is now given of each operation.

In operation S1 for providing the source gas S, the source gas S may be provided onto the substrate W and thus at least a part of the source gas S may be adsorbed onto the substrate W. The source gas S is provided through the first tube 110, the third tube 130, the mixing channel 230, and the inlet channel 355, which are located outside the process chamber 300, into the process chamber 300. The first inert gas may be provided together with the source gas S to carry the source gas S.

The substrate W may include, for example, a semiconductor substrate, a conductor substrate, or an insulator substrate. Optionally, an arbitrary pattern or layer may be already provided on the substrate W before a thin film is deposited thereon. The adsorption may include a well-known ALD scheme, e.g., chemical adsorption.

In operation S2 for providing the reaction gas R, the reaction gas R is provided through the second tube 120, the third tube 130, the mixing channel 230, and the inlet channel 355, which are located outside the process chamber 300, into the process chamber 300. The second inert gas may be provided together with the reaction gas R to carry the reaction gas R.

In operation S3 for activating the reaction gas R on the substrate W to the plasma state, the part of the source gas S adsorbed onto the substrate W may react with the reaction gas R of the plasma state to deposit the unit film. According to the technical idea of the present invention, the reaction gas R may be formed of a material which does not react with the source gas S in a non-plasma state.

Plasma mentioned in this specification may be produced by using, for example, a direct plasma scheme. The direct plasma scheme includes, for example, a method of directly producing plasma of the reaction gas R in a process space of the process chamber 300 between electrodes and the substrate W by supplying the reaction gas R into the process space and applying high-frequency power thereto.

The unit film is a unit element of a thin film to be deposited. For example, if the unit cycle T is repeatedly performed N times (where N is a positive integer equal to or greater than 1), the ultimately deposited thin film may include N unit films.

In operation S4 for providing the first inert gas onto the substrate W, the first inert gas is provided through the first tube 110, the third tube 130, the mixing channel 230, and the inlet channel 355, which are located outside the process chamber 300, into the process chamber 300. The first inert gas may be formed of a material which does not chemically react with the source gas S and the reaction gas R. For example, the first inert gas may be a nitrogen gas, an argon gas, or a gas mixture of a nitrogen gas and an argon gas. The first inert gas may at least subsidiarily carry the source gas S and may purge non-reacted residues remaining on the substrate W.

In operation S5 for providing the second inert gas onto the substrate W, the second inert gas is provided through the second tube 120, the third tube 130, the mixing channel 230, and the inlet channel 355, which are located outside the process chamber 300, into the process chamber 300. The second inert gas may be formed of a material which does not chemically react with the source gas S and the reaction gas R. For example, the second inert gas may be a nitrogen gas, an argon gas, or a gas mixture of a nitrogen gas and an argon gas. The second inert gas may at least subsidiarily carry the reaction gas R and may purge non-reacted residues remaining on the substrate W.

According to the technical idea of the present invention, the source gas S and the reaction gas R may be provided into the process chamber 300 in the form of a gas mixture. For example, during the above-described first period t1, the source gas S passed through the first tube 110 and the reaction gas R passed through the second tube 120 are primarily mixed in the third tube 130 due to flow interference therebetween, and then the gas mixture is further mixed while passing through the mixing block 200 including the internal space 250 and the collision part 270. As such, the uniformly mixed gas mixture may be provided into the process chamber 300.

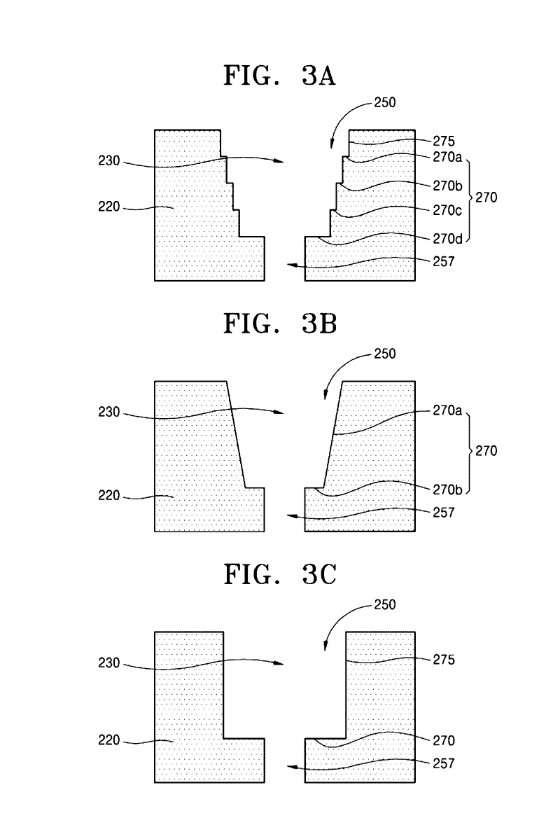

FIG. 2 is a view showing thickness uniformities of thin films deposited on substrates using substrate processing apparatuses according to an embodiment and a comparative example of the present invention.

Six thickness uniformity maps illustrated at an upper part of FIG. 2 show thickness uniformities of thin films deposited on substrates using the substrate processing apparatus 10b illustrated in FIG. 1B according to a comparative example of the present invention. Meanwhile, six thickness uniformity maps illustrated at a lower part of FIG. 2 show thickness uniformities of thin films deposited on substrates using the substrate processing apparatus 10a illustrated in FIG. 1A according to an embodiment of the present invention. To consider significant differences depending on apparatuses, three different apparatuses are used for tests and marked with (a), (b), and (c).

Referring to FIG. 2, it is shown that the thickness uniformities of the thin films deposited on the substrates using the substrate processing apparatuses according to a comparative example of the present invention are 0.47%, 0.54%, 0.53%, 0.47%, 0.51%, and 0.45%, and that the thickness uniformities of the thin films deposited on the substrates using the substrate processing apparatuses according to an embodiment of the present invention are 0.36%, 0.37%, 0.38%, 0.33%, 0.29%, and 0.32%, which are relatively good.

Furthermore, the thickness uniformity maps according to an embodiment of the present invention more clearly show concentric forms compared to those according to a comparative example of the present invention. To achieve symmetry of top, bottom, left and right parts on a substrate, a concentric form of a thickness map is preferable. On the other hand, asymmetry of at least one of top, bottom, left and right parts of a thickness map may exert a bad influence on a product yield. Although improvement of an average value of thickness uniformities through adjustment of pressure in a chamber, gas conditions, or the like is advantageous in actual processes, implementation of the concentric form is related to a hardware configuration of an apparatus and thus may not be easy. According to embodiments of the present invention, concentric thickness uniformity may be easily implemented by employing the mixing block 200 including the internal space 250 and the collision part 270.

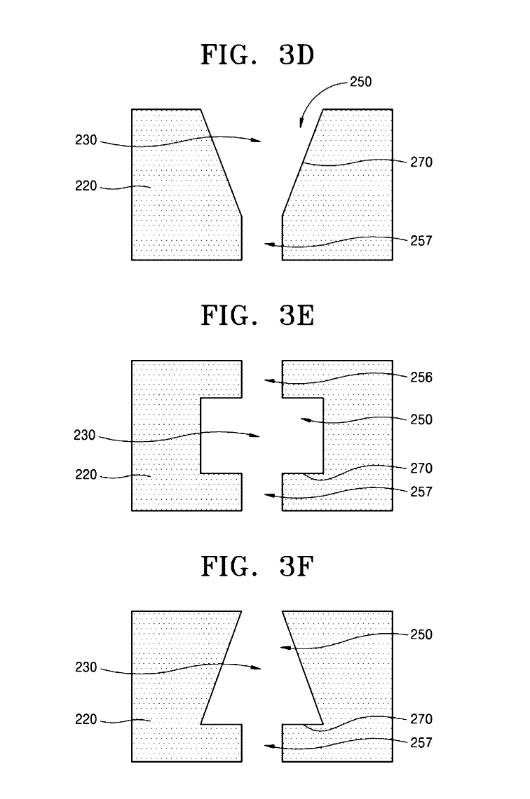

A description is now given of various types of mixing blocks for configuring substrate processing apparatuses according to embodiments of the present invention. Accordingly, the substrate processing apparatuses according to various embodiments of the present invention may be implemented by replacing the mixing block 200 illustrated in FIG. 1A with mixing blocks illustrated in FIGS. 3A to 3F.

Referring to FIGS. 1A and 3A, the mixing block includes the body 220 including the mixing channel 230. The mixing channel 230 includes the internal space 250 capable of expanding a cross-sectional area of the path of the gas mixture passed through the feeding block 100 to diffuse the gas mixture of the source gas S and the reaction gas R. For example, since the internal space 250 has a cross-sectional area larger than the cross-sectional area of the third tube 130 of the feeding block 100, the gas mixture may be rapidly diffused due to pressure drop on the path thereof. In addition, the mixing block 200 includes the collision part 270 provided on the path of the diffused gas mixture to generate a vortex of the gas mixture. The collision part 270 may include collision surfaces which are not parallel but perpendicular to a direction proceeding from the feeding block 100 toward the shower head 350.

An outlet 257 of the mixing channel 230 may be communicated with the inlet channel 355 of the shower head 350.

Particularly, the mixing channel 230 illustrated in FIG. 3A includes regions having cross-sectional areas which decrease step by step along the path of the gas mixture. For example, the internal space 250 may include multiple cylindrical spaces having cross-sectional areas which decrease step by step. In this case, the cross-sectional area of at least a top cylindrical space among the multiple cylindrical spaces may be larger than the cross-sectional area of the third tube 130.

The collision part 270 provides surfaces which are perpendicular to the path of the gas mixture, and includes steps 270a to 270d provided at edges of the regions having cross-sectional areas which decrease step by step.

Although side surfaces 275 for interconnecting the steps 270a to 270d are parallel to the path of the gas mixture in FIG. 3A, if necessary, the side surfaces 275 may be configured to form a specific angle from the path of the gas mixture. In this case, the side surfaces 275 forming a specific angle may also serve as collision surfaces to generate a vortex of the gas mixture.

Referring to FIGS. 1A and 3B, the mixing block includes the body 220 including the mixing channel 230. The mixing channel 230 includes the internal space 250 capable of expanding a cross-sectional area of the path of the gas mixture passed through the feeding block 100 to diffuse the gas mixture of the source gas S and the reaction gas R. For example, since an inlet of the internal space 250 has a cross-sectional area larger than the cross-sectional area of the third tube 130 of the feeding block 100, the gas mixture may be rapidly diffused due to pressure drop on the path thereof. In addition, the mixing block 200 includes the collision part 270 provided on the path of the diffused gas mixture to generate a vortex of the gas mixture.

Particularly, the mixing channel 230 illustrated in FIG. 3B includes a region having a linearly decreasing cross-sectional area along the path of the gas mixture. For example, the internal space 250 may include a truncated conical space having a linearly decreasing cross-sectional area. In this case, the cross-sectional area of at least a top part of the truncated conical space may be larger than the cross-sectional area of the third tube 130.

The collision part 270 includes a surface 270a and a surface 270b which are diagonal and perpendicular to the path of the gas mixture, respectively. The perpendicular surface 270b includes a step provided at an edge of the region having a linearly decreasing cross-sectional area.

The mixing block may have a variety of modified forms in addition to the above-described forms.

The mixing channel 230 illustrated in FIG. 3C includes the internal space 250 provided as a region having a constantly maintained cross-sectional area along the path of the gas mixture. The collision part 270 includes a surface which is perpendicular to the path of the gas mixture. For example, the collision part 270 includes a step provided at an edge of the region having a constantly maintained cross-sectional area.

The mixing channel 230 illustrated in FIG. 3D includes the internal space 250 provided as a region having a linearly decreasing cross-sectional area along the path of the gas mixture, and the collision part 270 includes a surface which is diagonal to the path of the gas mixture. A collision surface which is perpendicular to the path of the gas mixture is not used in FIG. 3D.

The mixing channel 230 illustrated in FIG. 3E includes the internal space 250 provided as a region having a cross-sectional area which is expanded compared to an inlet 256. The internal space 250 constantly maintains the cross-sectional area along the path of the gas mixture. The cross-sectional area of the internal space 250 is larger than the cross-sectional area of the third tube 130. The collision part 270 includes a collision surface which is perpendicular to the path of the gas mixture, and the collision surface may be understood as a step provided at an edge of the region having the constantly maintained cross-sectional area.

The mixing channel 230 illustrated in FIG. 3F includes the internal space 250 provided as a region having a linearly increasing cross-sectional area along the path of the gas mixture. The collision part 270 includes a collision surface which is perpendicular to the path of the gas mixture. The perpendicular collision surface includes a step provided at an edge of the region having a linearly increasing cross-sectional area.

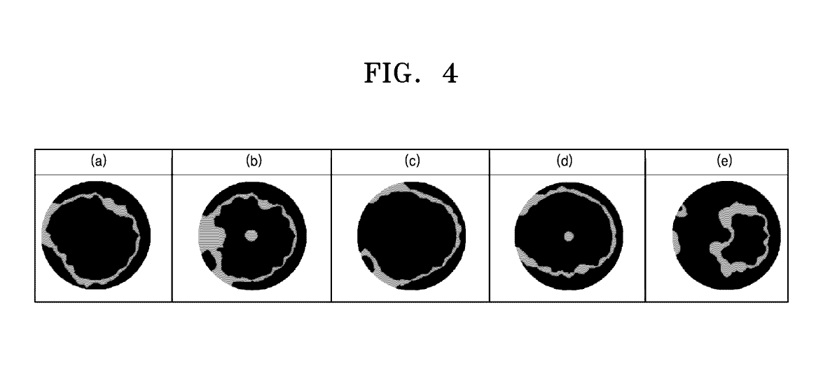

FIG. 4 is a view showing thickness uniformities of thin films deposited on substrates using substrate processing apparatuses including the mixing blocks illustrated in FIGS. 3A to 3E.

Referring to FIG. 4, thickness uniformity maps of the thin films deposited on the substrates using the substrate processing apparatuses including the mixing blocks according to various embodiments of the present invention show concentric forms. According to various embodiments of the present invention, concentric thickness uniformity may be easily implemented by employing the mixing block 200 including the internal space 250 and the collision part 270.

As described above, according to the embodiments of the present invention, a substrate processing apparatus is capable of improving thickness uniformity of a deposited thin film. However, the scope of the present invention is not limited to the above effect.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A substrate processing apparatus comprising:
a process chamber comprising a shower head;
a feeding block comprising a tube to provide a source gas and a reaction gas to the shower head; and
a mixing block configured to provide a channel connected between the shower head and the feeding block to mix the source gas and the reaction gas,
wherein the mixing block comprises:
an internal space having a cross-sectional area larger than the cross-sectional area of the tube provided in the feeding block; and
a collision part provided on a path of a gas mixture of the source gas and the reaction gas to collide with the gas mixture.

2. The substrate processing apparatus of claim 1, wherein the tube provided in the feeding block comprises:
a first tube capable of providing the source gas;
a second tube capable of providing the reaction gas; and
a third tube directly connected to the first and second tubes, extending to be connected to the internal space of the mixing block, and capable of providing the source gas and the reaction gas, and
wherein the internal space of the mixing block is in fluid communication with the third tube and has a cross-sectional area larger than the cross-sectional area of the third tube to diffuse the gas mixture of the source gas and the reaction gas.

3. The substrate processing apparatus of claim 1, wherein the collision part comprises a collision surface which is not parallel but diagonal or perpendicular to a direction from the feeding block toward the shower head.

4. The substrate processing apparatus of claim 1, wherein the internal space provided in the mixing block comprises multi-stage cylindrical spaces having decreasing cross-sectional areas.

5. The substrate processing apparatus of claim 1, wherein the internal space provided in the mixing block comprises a truncated conical space having a continuously decreasing cross-sectional area.

6. The substrate processing apparatus of claim 1, wherein the internal space provided in the mixing block comprises a cylindrical space having a uniform cross-sectional area.

7. The substrate processing apparatus of claim 2, wherein each of the first and second tubes lies perpendicular to the third tube, and wherein the first and second tubes extend in opposite directions from the third tube.

8. The substrate processing apparatus of claim 2, wherein the first and second tubes are located at different levels.

9. The substrate processing apparatus of claim 2, wherein the first and second tubes are located at the same level.

10. The substrate processing apparatus of claim 1, wherein the mixing block comprises an insulating member between the feeding block and the shower head.

11. The substrate processing apparatus of claim 1, wherein the mixing block is made of ceramic material or Al₂O₃.

12. The substrate processing apparatus of claim 1, wherein the source gas comprises a silicon-containing gas,
wherein the reaction gas comprises an oxygen-containing gas, and
wherein the gas mixture further comprises an inert gas.
